(19) United States
(12) Patent Application Publication
(10) Pub. No.: US 2002/0196951 A1
(43) Pub. Date: Dec. 26, 2002

(54) System for automatically performing a frequency response equalization tuning on speaker of electronic device

(76) Inventor: Kuo-Liang Tsai, Taipei (TW)

Correspondence Address: BACON & THOMAS, PLLC, 625 SLATERS LANE, FOURTH FLOOR, ALEXANDRIA, VA, 22314

(21) Appl. No.: 09/888,395

(22) Filed: Jun. 26, 2001

(51) Int. Cl. H03G 5/00; H04R 29/00

(52) U.S. Cl. 381/98; 381/59

(57) ABSTRACT

System for automatically performing a frequency response equalization tuning utilizes a central processing unit (CPU) in an electronic device to simulate and generate a standard sound signal having a predetermined bandwidth through a sound control circuit in order for a microphone to receive the signal for sending back to the CPU through the sound control circuit performing a frequency response matching with respect to a predetermined ideal frequency response data, calculating a set of equalization tuning gains, and storing the gains in a digital equalizer for automatically performing a frequency response equalization tuning on the speaker.

### FIELD OF THE INVENTION

The present invention relates to speakers of electronic device and more particularly to a system for automatically performing a frequency response equalization tuning on a speaker of electronic device.

### BACKGROUND OF THE INVENTION

As times revolves especially in recent decades the progress of technology has been significant. As a result, more and more people involve in a bustling daily life. For increasing work efficiency and improving living standard, various electronic devices have been developed such as electronic dictionary, electronic book, personal digital assistant (PDA), mobile phone, etc. And in turn, more and more people rely on such electronic devices in their daily life and even become an indispensable part in some people' daily life. Hence, having a high quality electronic device has become a common requirement among users.

Moreover, electronic dictionary, electronic notebook, PDA, mobile phone, etc. can provide necessary information to people for facilitating work and/or daily life. In each of above devices, an embedded speaker is operative to amplify sound therefrom. Hence, a good speaker is closely related to the sound quality of the electronic device. In view of this, current electronic device manufacturers always perform a frequency response matching on an installed speaker in the electronic device so as to obtain an optimum sound effect from the generated frequency response of speaker. Also, an optimum gain of speaker may be obtained by tuning resistance and capacitance of a coupled equalizer so as to effectively correct output frequency response of speaker. As a result, an optimum sound is generated in an audible frequency range of 20 Hz and 20 KHz.

Typically, an equalization tuning on a speaker installed in an electronic device is first performed by testing output sound of one of a plurality of different sampling frequencies by a test instrument. Then manually tune resistance and capacitance of a coupled equalizer repeatedly until an optimum frequency response output is obtained from speaker. However, the previous technique suffered from several disadvantages. For example, it is tedious, time consuming, and laborious. Further, above tedious tuning process has to be done again after the used speaker is replaced by a new one. And in turn technician may get tired of this, resulting in a poor tuning and quality. Above facts really bother electronic device manufacturers. Recently, a digital equalizer is employed to solve above problems by some electronic device manufacturers. However, an equalization tuning on a speaker installed in an electronic device is still first performed by testing output sound of one of a plurality of different sampling frequencies by a test instrument. Then input the obtained gain to be tuned into digital equalizer for obtaining an optimum output frequency response of speaker. By utilizing this, above tedious tuning process is still not improved. To the worse, above tedious tuning process has to be done again after the used speaker is replaced by a new one, resulting in a waste of labor and time. Thus improvement exists.

### SUMMARY OF THE INVENTION

It is therefore an object of the present invention in a system to provide a process for automatically performing a frequency response equalization tuning. The process comprises the steps of installing a speaker in an electronic device; commanding a central processing unit (CPU) in the electronic device to simulate and generate a standard sound signal having a predetermined bandwidth through a sound control circuit in the electronic device; commanding a digital equalizer in the electronic device to receive the standard sound signal and outputting the standard sound signal through a speaker in the electronic device; commanding a microphone to receive the standard sound signal for sending back to the CPU through the sound control circuit; commanding the CPU to perform a frequency response matching on the received sound signal with respect to a predetermined ideal frequency response data; calculating a set of equalization tuning gains in the predetermined bandwidth; inputting the gains in the digital equalizer for storing; and commanding the digital equalizer to automatically perform a frequency response equalization tuning on the speaker, thereby maintaining the output sound signal at an optimum frequency response state.

The above and other objects, features and advantages of the present invention will become apparent from the following detailed description taken with the accompanying drawings.

### BRIEF DESCRIPTION OF THE DRAWINGS

FIG. 1 is a block diagram of a preferred embodiment of system for automatically performing a frequency response equalization tuning on an embedded speaker of an electronic device according to the invention;

FIG. 2 is a flow chart illustrating the process of performing the equalization tuning of FIG. 1;

FIG. 3 is a frequency response graph of an ideal frequency response data;

FIG. 4 is a frequency response graph of a standard sound data; and

FIG. 5 is a frequency response graph of a digital sound data.

### DETAILED DESCRIPTION OF THE PREFERRED EMBODIMENTS

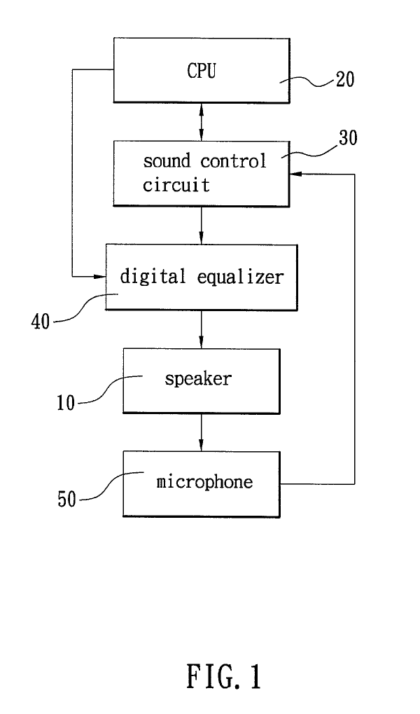

FIG. 1 is a block diagram of a preferred embodiment of system for automatically performing a frequency response equalization tuning on an embedded speaker of an electronic device according to the invention. The system comprises a speaker 10 in an electronic device, a central processing unit (CPU) 20 in the electronic device for simulating and generating a standard sound file in an audible frequency range of 20 Hz and 20 KHz, a sound control circuit 30 for receiving standard sound file from CPU 20 for generating a standard sound signal having a corresponding frequency range based on the standard sound file, a digital equalizer 40 for receiving the standard sound signal from sound control circuit 30 for performing an initial compensation on the standard sound signal based on a predetermined initial gain thereof, and a microphone 50 for receiving the standard sound signal from speaker 10 for further sending back to CPU 20 through sound control circuit 30. CPU 20 then performs a frequency response matching on the received sound signal with respect to a predetermined ideal frequency response value and thereafter calculates a set of equalization tuning gains corresponding to frequency response compensation performed in speaker 10. The obtained gains are further sent to digital equalizer 40 for storing. Hence, digital equalizer 40 may automatically perform a frequency response equalization tuning on the speaker 10. As a result, the output sound signals are always maintained at an optimum frequency response state.

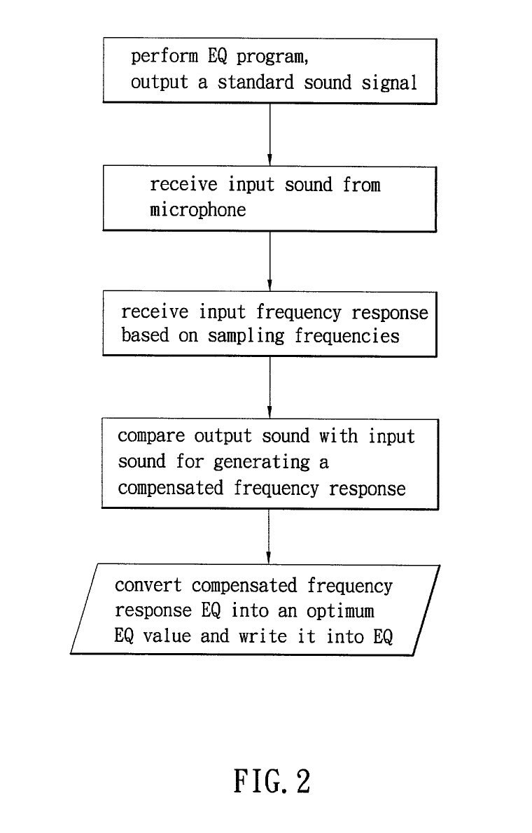

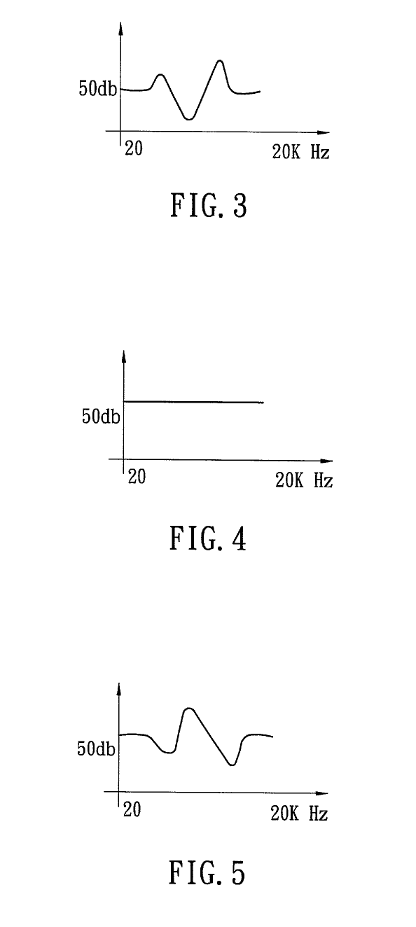

In the invention, a software installed in CPU 20 performs a frequency response compensation on speaker 10 in electronic device in the following steps as shown in the flow chart of FIG. 2. Firstly, electronic device is required to design an ideal frequency response data in an audible frequency range of 20 Hz and 20 KHz based on the specifications of speaker 10 to be installed. In FIG. 3, there is shown a frequency response graph of an ideal frequency response data. Such data is stored in a memory of electronic device. A standard sound data in an audible frequency range of 20 Hz and 20 KHz is stored in the memory as shown in FIG. 4 the frequency response graph of a standard sound data.

After speaker 10 is installed in electronic device, power of electronic device is then turned on. As shown in FIG. 2 again, CPU 20 reads the standard sound data from memory. Then CPU 20 sends it to sound control circuit 30 for generating a standard sound signal therein based on the standard sound data. Then digital equalizer 40 may compensate it based on a predetermined initial gain. The compensated sound signal is further sent to speaker 10. Once microphone 50 receives the compensated sound signal it will instruct sound control circuit 30 to convert the sound signal into a digital sound data as shown in FIG. 5 the frequency response graph of a digital sound data. Such digital sound data is further sent back to CPU 20.

At this time, CPU 20 will perform a frequency response matching on the received sound data with respect to the ideal frequency response data based on a plurality of sampling frequencies as shown in FIG. 2 again. Then CPU 20 calculates a set of equalization tuning gains corresponding to frequency response compensation performed in speaker 10 in each of the plurality of sampling frequencies. The obtained gains are further sent to digital equalizer 40 for storing. Hence, digital equalizer 40 may automatically perform a frequency response equalization tuning on the speaker 10. As a result, the output sound signals, in the audible frequency range of 20 Hz and 20 KHz, are always maintained at an optimum frequency response state conformed to the ideal frequency response values of FIG. 3.

In brief, after speaker 10 is installed in electronic device, power of the electronic device is then turned on. By utilizing the invention, it is possible of automatically detecting and calculating equalization tuning gains in the audible frequency range of 20 Hz and 20 KHz. Hence, digital equalizer 40 may automatically perform a frequency response tuning on the speaker 10. In view of above, in the electronic device of the invention after the installation of speaker, a technician does not have to perform a tedious testing process on output sound of one of a plurality of different sampling frequencies by a test instrument. Nor does the technician have to manually tune resistance and capacitance of a coupled equalizer repeatedly. To the contrary, the invention can tune the output sound signals of speaker to an optimum frequency response state.

While the invention has been described by means of specific embodiments, numerous modifications and variations could be made thereto by those skilled in the art without departing from the scope and spirit of the invention set forth in the claims.

What is claimed is:

1. In a system a process for automatically performing a frequency response equalization tuning, said process comprising the steps of:
installing a speaker in an electronic device;
commanding a central processing unit (CPU) in said electronic device to simulate and generate a standard sound signal having a predetermined bandwidth through a sound control circuit in said electronic device;
commanding a digital equalizer in said electronic device to receive said standard sound signal and outputting said standard sound signal through a speaker in said electronic device;
commanding a microphone to receive said standard sound signal for sending back to said CPU through said sound control circuit;
commanding said CPU to perform a frequency response matching on said received sound signal with respect to a predetermined ideal frequency response data;
calculating a set of equalization tuning gains in said predetermined bandwidth;
inputting said gains in said digital equalizer for storing; and
commanding said digital equalizer to automatically perform a frequency response equalization tuning on said speaker, thereby maintaining said output sound signal at an optimum frequency response state.

2. The process of claim 1, wherein said electronic device is manufactured to have said predetermined ideal frequency response data with said predetermined bandwidth based on specifications of said speaker to be installed in said electronic device prior to storing said ideal frequency response data in a memory of said electronic device so that when said electronic device is enabled a predetermined software in said CPU reads said ideal frequency response data from said memory for generating said standard sound signal having said predetermined bandwidth through said sound control circuit.

3. The process of claim 1, wherein after said digital equalizer has received said sound signal from said sound control circuit, further comprising the steps of commanding said digital equalizer to compensate said sound signal based on a predetermined initial gain, and sending said compensated sound signal to said speaker for outputting.

4. The process of claim 1, wherein after said microphone has received said compensated sound signal, further comprising said steps of commanding said sound control circuit to convert said sound signal into a digital sound data, and sending said digital sound data back to said CPU.

5. The process of claim 1, further comprising said steps of:
commanding said CPU to perform a frequency response matching on said received sound signal with respect to said outputted standard sound signal based on a plurality of sampling frequencies;
calculating a set of equalization tuning gains corresponding to said frequency response compensation performed in said speaker in each of said plurality of sampling frequencies; and
inputting said gains in said digital equalizer for storing.

6. The process of claim 1, wherein said standard sound signal having said predetermined bandwidth is a standard sound file in an audible frequency range of 20 Hz and 20 KHz.
